(19) United States
(12) Patent Application Publication
(10) Pub. No.: US 2025/0038104 A1
(43) Pub. Date: Jan. 30, 2025

(54) INTEGRATED CIRCUITS WITH CAPACITORS

(71) Applicant: Adeia Semiconductor Bonding Technologies Inc., San Jose, CA (US)

(72) Inventors: Rajesh Katkar, Milpitas, CA (US); Belgacem Haba, Saratoga, CA (US)

(21) Appl. No.: 18/759,139

(22) Filed: Jun. 28, 2024

Related U.S. Application Data
(60) Provisional application No. 63/511,633, filed on Jun. 30, 2023.

(51) Int. Cl. H01L 23/522; H01L 23/00; H01L 23/528; H01L 25/065; H01L 25/16; H01L 29/94

(52) U.S. Cl. CPC H01L 23/5223; H01L 23/5286; H01L 24/02; H01L 24/05; H01L 24/06; H01L 24/08; H01L 24/80; H01L 25/0657; H01L 25/16; H01L 29/945; H01L 2224/02381; H01L 2224/05548; H01L 2224/05567; H01L 2224/05573; H01L 2224/05724; H01L 2224/05744; H01L 2224/05747; H01L 2224/05755; H01L 2224/0603; H01L 2224/08265; H01L 2224/80895; H01L 2225/06524; H01L 2225/06565; H01L 2924/30105; H01L 2924/3011

(57) ABSTRACT

A component comprises a substrate comprising a first side and a second side opposite to the first side. A first dielectric layer is formed on the first side, and a plurality of electrically conductive pads extend through the first dielectric layer. A second dielectric layer is formed on the second side, and a plurality of electrically conductive pads extend through the second dielectric layer. A plurality of capacitors are each formed in an opening that extends at least partially from the first side towards the second side of the substrate. Each of the capacitors comprises at least three electrodes. At least one of the plurality of capacitors is coupled on the first side to an electrically conductive pad of the first dielectric layer and is coupled on the second side to an electrically conductive pad of the second dielectric layer.

### CROSS-REFERENCE TO RELATED APPLICATION

This application claims the benefit of U.S. Provisional Patent Application No. 63/511,633, filed Jun. 30, 2023, which is hereby incorporated by reference in its entirety.

### FIELD

The present disclosure generally relates to semiconductor device manufacturing and assembly and, more particularly, to integrated circuits formed with capacitors and methods of forming the integrated circuits.

### SUMMARY

Embodiments herein include integrated circuits formed with capacitors, and methods of forming thereof. In some embodiments, the integrated circuits (e.g., passive or active) include a plurality of capacitors, each of which comprises three electrodes. In some embodiments, each capacitor may comprise at least three electrodes. In some embodiments, each capacitor may comprise three or more electrodes.

In some embodiments, a component for a plurality of capacitors each comprising at least three electrodes is provided. The component comprises a substrate comprising a first side and a second side opposite to the first side. A first dielectric layer is formed on the first side and comprises a plurality of electrically conductive pads extending through the first dielectric layer. A second dielectric layer is formed on the second side and comprises a plurality of electrically conductive pads extending through the second dielectric layer. The component comprises a plurality of capacitors which are each formed in an opening or a cavity that extends at least partially from the first side of the substrate towards the second side of the substrate. In some embodiments, the component comprises a plurality of capacitors which are each formed in an opening that extends from the first side of the substrate to the second side of the substrate. At least one of the plurality of capacitors is coupled on the first side to an electrically conductive pad of the first dielectric layer and is coupled to on the second side to an electrically conductive pad of the second dielectric layer. In some embodiments, the plurality of capacitors comprise pass-through capacitors.

In some embodiments, an integrated circuit device (e.g., a passive or an active chip) is attached to the first dielectric layer of the component. The integrated circuit device may be electrically coupled to at least one of the electrically conductive pads of the first dielectric layer.

In some embodiments, the capacitors can directly provide access to power and ground or positive and negative voltage through the electrically conductive pads in the second dielectric layer and directly provide the power and ground or positive and negative voltage to the component to the integrated circuit device, which may remove the need for separate ground vias and power vias (e.g., in another portion of the substrate). Advantageously, the size of large arrays of capacitors (e.g., massive capacitors) can be reduced. By directly accessing power or ground, the distance that power or ground has to travel to the capacitor (and/or the integrated circuit device) may be reduced, thereby reducing impedance in large arrays of capacitors. Each of the plurality of capacitors can be coupled to a distinct power or ground connection, thereby providing an arrangement where each of the capacitors can carry varying voltages which allows for multiple voltage regions to be present in massive capacitors. This may enable a massive capacitor that can provide capacitance to a plurality of integrated circuit devices with different power and ground requirements.

In some embodiments, the first dielectric layer can be a redistribution layer further comprising a plurality of conductive layers formed in the first dielectric layer. The plurality of conductive layers or at least a group of the plurality of conductive layers may electrically couple the plurality of capacitors or at least a group of the plurality of capacitors to each other. This may provide improved distribution of power and ground to and from each of the plurality of capacitors or at least the group of the plurality of capacitors, thereby reducing overall impedance in the massive capacitor.

In some embodiments, the plurality of conductive layers of the redistribution layer may be patterned to electrically couple groups of capacitors to each other. In some embodiments, the redistribution layer may further comprise fuse or anti-fuse components to electrically couple or separate groups of capacitors. The fuse or anti-fuse component may be used to electrically couple or separate groups of capacitors post-manufacturing. This may enable generating capacitors with having particular effective capacitances (e.g., groups of capacitors has effective capacitance as the sum of individual capacitances).

In some embodiments, the plurality of capacitors may be coupled to one of the electrically conductive pads of the second dielectric layer. In some embodiments, a group of capacitors may be coupled to one electrically conductive pad of the second dielectric layer. In some embodiments, the group of capacitors may be coupled to separate conductive pads in the first dielectric layer that are connected through a conductive layer in the redistribution layer. This may enable generating capacitors with having particular effective capacitances (e.g., groups of capacitors has effective capacitance as the sum of individual capacitances).

In some embodiments, the component can further comprise a via formed in the substrate. The via comprises a conductive layer (e.g., to carry a signal). The conductive layer is coupled to a third electrically conductive pad extending through the first dielectric layer and a second electrically conductive pad extending through the second dielectric layer. Advantageously, the component can pass signals from one component to another component (e.g., from one integrated circuit device to another integrated circuit device) while also acting as a massive capacitor. In some embodiments, the via may carry power or ground.

In some embodiments, a method of forming a plurality of capacitors is provided. The method comprises forming a plurality of openings or cavities on a first side of a substrate, the substrate comprising the first side and a second side opposite the first side. The method further comprises patterning a capacitor in each of the plurality of openings or cavities and etching a portion of the second side of the substrate to reveal a portion of each of the capacitors. Each capacitor comprises at least three electrodes. The method further comprises forming a first dielectric layer on the first side of the substrate, the first dielectric layer comprising a first plurality of electrically conductive pads extending through the first dielectric layer and coupled to the capacitors. The method further comprises forming a second dielectric layer on the second side of the substrate, the second dielectric layer comprising a second plurality of electrically conductive pads extending through the second dielectric layer and coupled to the capacitors.

In some embodiments, the component comprises capacitors that are not pass-through capacitors and may comprise one or more other passive electronic components such as a resistor, an inductor, a voltage regulator, a filter, and/or a resonator. In some embodiments, the component comprises pass-thru capacitors and may comprise one or more other passive electronic components such as a capacitor that is not a pass-thru capacitor, a resistor, an inductor, a voltage regulator, a filter, and/or a resonator. In some embodiments, the first dielectric layer (e.g., dielectric layer with first and second electrodes/pads) or redistribution layer (e.g., further comprising conductive layers to redistribute the pad layout) of the component faces a device it is attached to and the second dielectric layer (e.g., dielectric layer with third electrode/pad) faces away from the device. In some embodiments, the second dielectric layer (e.g., dielectric layer with third electrode/pad) faces a device it is attached to and the first dielectric layer (e.g., dielectric layer with first and second electrodes/pads) faces away from the device.

In some embodiments, the component may be attached to one device or chip. In some embodiments, the component may be used to connect multiple devices or chips, and may be referred to as an interposer. In some embodiments, multiple device or chips may be attached one side of the component. In some embodiments, multiple devices or chips may be attached to opposite sides of the component. The component may be a same size or smaller or larger in size that the device or chip it is attached to.

In some embodiments, the component may have a distribution of power and ground pads or positive and negative voltage pads on both sides of the component. For example, the component may have a redistribution layer on each side of the component. Having redistribution layer on each side of the component may help prevent or reduce a curvature or bending of the component.

In some embodiments, the component may have power and ground pads or positive and negative voltage pads that are distributed across surfaces of the component. The power and ground or positive and negative voltages may be selected anywhere on a surface of the component. For example, a device that is attached to the component may directly have access to power or ground through groups of capacitors of the component. In some embodiments, groups of capacitors may be used for power and ground for multiple V_{DD} (e.g., power supply voltage of a device) and V_{SS} (e.g., ground supply voltage of a circuit).

In some embodiments, the component may comprise capacitors with more than three electrodes. For example, a pass thru capacitor may have additional first, second or third electrodes to help distribute connections to the plates of the capacitor.

In some embodiments, the pads or electrodes providing ground or negative voltage of all the capacitors in an array of capacitors (e.g., massive capacitor) may be electrically connected. In some embodiments, the pads or electrodes providing power or positive voltage of all the capacitors in an array of capacitors (e.g., massive capacitor) may be electrically connected. In some embodiments, groups of pads or electrodes providing ground may be electrically connected to each other but not other groups. In some embodiments, groups of capacitors in an array of capacitors may be electrically connected.

In some embodiments, the component may be an integrated component (e.g., attached to one or more device, chip, or element). In some embodiments, the component may be a passive component (e.g., comprising passive elements or devices). In some embodiments, the component may be an active component. For example, the component may further comprise an active device and be an integrated active component.

### BRIEF DESCRIPTION OF DRAWING

The above and other objects and advantages of the disclosure will be apparent upon consideration of the following detailed description, taken in conjunction with the accompanying drawings, in which:

FIG. 1A is a schematic cross-sectional view of a component, in accordance with some embodiments of the disclosure;

FIG. 1B is a schematic diagram a capacitor with three electrodes, in accordance with some embodiments of the disclosure;

FIG. 1C is a schematic cross-sectional view of a portion of a capacitor, in accordance with some embodiments of the disclosure;

FIG. 1D is a schematic cross-sectional view of a portion of a capacitor, in accordance with some embodiments of the disclosure;

FIG. 1E is a schematic cross-sectional view of a second dielectric layer of a component, in accordance with some embodiments of the disclosure;

FIG. 1F is a schematic cross-sectional view of a portion of a capacitor, in accordance with some embodiments of the disclosure;

FIG. 1G is a schematic cross-sectional view of a portion of a capacitor, in accordance with some embodiments of the disclosure;

FIG. 2 is a schematic cross-sectional view of an integrated component with capacitors and vias integrally coupled to two devices, in accordance with some embodiments of the disclosure;

FIG. 3 is a schematic cross-sectional view of an integrated component with capacitors integrally coupled to two devices, in accordance with some embodiments of the disclosure;

FIG. 4 is a flowchart of illustrative steps involved in forming a component, in accordance with some embodiments of the disclosure; and

FIG. 5 is a flowchart of illustrative steps involved in forming an integrated component, in accordance with some embodiments of the disclosure.

The figures herein depict various embodiments of the invention for purposes of illustration only. It will be appreciated that additional or alternative structures, systems and methods may be implemented within the principles set out by the present disclosure.

### DETAILED DESCRIPTION

As used herein, the term “substrate” means and includes any workpiece, wafer, or article that provides a base material or supporting surface from which or upon which components, elements, devices, assemblies, modules, systems, or features of the integrated circuits, capacitors, devices, and components described herein may be formed or mounted. The term substrate also includes “semiconductor substrates” that provide a supporting material upon which elements of a semiconductor device are fabricated or attached, and any material layers, features, and/or electronic devices formed thereon, therein, or therethrough. Examples of substrate material that may be used include, but are not limited to, a semiconductor material, Si, glass, GaN, SiC, InP, GaP, InGaN, AlGaInP, AlGaAs, etc. In some embodiments, a low CTE material (e.g., glass, ceramic) may be used. In some other embodiments, substrate material that may be used include organic (e.g. polyimide, PBO, etc.) or inorganic (e.g. silicon oxide, silicon nitride, etc.) material.

As described below, the semiconductor substrates herein generally have a “device side,” e.g., the side on which semiconductor device elements are fabricated, such as transistors, resistors, and capacitors, and a “backside” that is opposite the device side. The term “active side” should be understood to include a surface of the device side of the substrate and may include the device side surface of the semiconductor substrate and/or a surface of any material layer, device element, or feature formed thereon or extending outwardly therefrom, and/or any openings formed therein. Thus, it should be understood that the material(s) that form the active side may change depending on the stage of device fabrication and assembly. Similarly, the term “non-active side” (opposite the active side) includes the non-active side of the substrate at any stage of device fabrication, including the surfaces of any material layer, any feature formed thereon, or extending outwardly therefrom, and/or any openings formed therein. Thus, the terms “active side” or “non-active side” may include the respective surfaces of the semiconductor substrate at the beginning of device fabrication and any surfaces formed during material removal, e.g., after substrate thinning operations. Depending on the stage of device fabrication or assembly, the terms “active sides” and “non-active sides” are also used to describe surfaces of material layers or features formed on, in, or through the semiconductor substrate, whether or not the material layers or features are ultimately present in the fabricated or assembled device. For example, in some instances, the term “active side” is used to indicate a surface of a substrate that will in the future, but does not yet, include semiconductor device elements.

Spatially relative terms are used herein to describe the relationships between elements, such as the relationships between substrates, layers, and other features described below. Unless the relationship is otherwise defined, terms such as “above,” “over,” “upper,” “upwardly,” “outwardly,” “on,” “below,” “under,” “beneath,” “lower,” “top,” “bottom” and the like are generally made with reference to the X, Y, and Z directions set forth by X, Y and Z axis in the drawings. Thus, it should be understood that the spatially relative terms used herein are intended to encompass different orientations of the substrate and, unless otherwise noted, are not limited by the direction of gravity. Unless the relationship is otherwise defined, terms describing the relationships between elements such as “disposed on,” “embedded in,” “coupled to,” “connected by,” “attached to,” “bonded to,” either alone or in combination with a spatially relevant term include both relationships with intervening elements and direct relationships where there are no intervening elements. Furthermore, the term “horizontal” is generally made with reference to the X-axis direction and the Y-axis direction set forth in the drawings. The term “vertical” is generally made with reference to the Z-axis direction set forth in the drawings.

Various embodiments disclosed herein include bonded structures in which two or more elements are directly bonded to one another without an intervening adhesive (referred to herein as “direct bonding”, or “directly bonded”). In some embodiments, direct bonding includes the bonding of a single material on the first of the two or more elements and a single material on a second one of the two or more elements, where the single material on the different elements may or may not be the same. For example, bonding a layer of one inorganic dielectric (e.g. silicon oxide) to another layer of the same or different inorganic dielectric. Examples of dielectric materials used in direct bonding include oxides, nitrides, oxynitrides, carbonitrides, and oxycarbonitrides, etc., such as, for example, silicon oxide, silicon nitride, silicon oxynitride, silicon carbonitride, silicon oxycarbonitride, etc. Direct bonding can also include bonding of multiple materials on one element to multiple materials on the other element (e.g., hybrid bonding). As used herein, the term “hybrid bonding” refers to a species of direct bonding having both i) at least one (1^{st}) nonconductive feature directly bonded to another (2^{nd}) nonconductive feature, and ii) at least one (1^{st}) conductive feature directly bonded to another (2^{nd}) conductive feature, without any intervening adhesive. In some hybrid bonding embodiments, there are many 1^{st} conductive features, each directly bonded to a 2^{nd} conductive feature, without any intervening adhesive. In some embodiments, nonconductive features on the first element are directly bonded to nonconductive features of the second element at room temperature without any intervening adhesive, which is followed by bonding of conductive features of the first element directly bonded to conductive features of the second element at via annealing at slightly higher temperatures (e.g. >100° C., >200° C., >250° C., >300° C., etc.).

The hybrid bonding methods described herein generally include forming conductive features in the dielectric surfaces of the to-be-bonded substrates, activating the surfaces to open chemical bonds in the dielectric material, and terminating the surfaces with a desired species. In some embodiments, activating the surface may weaken chemical bonds in the dielectric material. Activating and terminating the surfaces with a desired species may include exposing the surfaces to radical species formed in a plasma. In some embodiments, the plasma is formed using a nitrogen-containing gas, e.g., N2, or forming gas and the terminating species includes nitrogen and hydrogen. In some embodiments, the surfaces may be activated using a wet cleaning process, e.g., by exposing the surfaces to aqueous solutions. In some embodiments, the aqueous solution is tetramethylammonium hydroxide diluted to a certain degree or percentage. In some embodiments, an aqueous solution may be ammonia. In some embodiments, the plasma is formed using a fluorine-containing gas, e.g., fluorine gas or helium containing a small amount of fluorine and/or nitrogen such as about 10% or less by volume, 9% or less, 8% or less, 7% or less, 6% or less, 5% or less, 4% or less, 3% or less, 2% or less, for example 1% or less.

Typically, the hybrid bonding methods further include aligning the substrates, and contacting the activated surfaces to form direct dielectric bonds. After the dielectric bonds are formed, the substrates may be heated to a temperature between 50° C. to 150° C. or more, or of 150° C. or more and maintained at the elevated temperature for a duration of about 1 hour or more, such as between 8 and 24 hours, to form direct metallurgical bonds between the metal features.

In the field of semiconductors, capacitors may be used for filtering, smoothing ripple voltages, power delivery, decoupling, and/or timing of integrated circuit devices, etc. To reliably provide adequate smooth power to high-power integrated devices (e.g., processors and high-power memory), it may be desirable to reduce the electrical path between capacitors and devices. This may be done by placing an array of capacitors (e.g., a massive capacitor) close to or directly onto an integrated circuit device or between the power supply and integrated circuit devices.

Massive capacitors as described herein may refer to large array of capacitors. Capacitors may be in discrete units (e.g., integrated passive devices (IPDs), Si deep trench capacitors, etc.) that have a smaller footprint compared to a device, chip, or element that the capacitor is attached to. Such IPDs may have limited number of IOs indicating limited number of capacitors or capacitor values (each capacitor value may require one positive and one negative electrode). Massive passive or massive capacitors, on the contrary, may have an identical or same or similar footprint as the chip, device, element it is attached to, and may be attached in a wafer to wafer (W2 W) hybrid bonding process. Such large area may also provide abundance of capacitors (as compared to limited Si caps or capacitors) that could be distributed based on the chip functional blocks, power distribution, workload requirements, etc.

Massive capacitors may comprise vias (e.g., through silicon vias (TSVs)) to provide power and ground to an integrated circuit device, as well as an array of a plurality of capacitors (e.g., deep trench capacitors) each formed in cavities of a substrate, and a dielectric layer formed on a top side of the substrate, covering the capacitors. The dielectric layer may have electrically conductive pads (e.g., to couple the integrated circuit device to the capacitors) extending through the dielectric layer and coupled to the capacitors. The plurality of capacitors may be coupled to the power and ground vias (e.g., through conductive layers in the dielectric layer) to provide a constant source of power and ground to all of the plurality of capacitors.

Although providing a substrate with an array of capacitors directly onto an integrated circuit device reduces the path from the capacitors to the device, each of the plurality of capacitors may still rely on a separate source of power and ground. Each of the capacitors may have electrodes only on one side of the substrate (e.g., land-side decoupling capacitor) providing limited access to positive and negative electrodes. This leads to a number of problems in the current industry approaches to the routing of power and ground lines. For example, massive capacitors may require each capacitor in the array of capacitors to draw power/ground from a separate power/ground TSV which can be far away from the capacitors. This can result in large impedance and, in turn, slower processing of the coupled integrated circuit device. Furthermore, it may not be possible to individually vary the voltage of each capacitor within the massive capacitor with present arrangements. Therefore, massive capacitors may not provide capacitance to a plurality of integrated circuit devices or more complex integrated circuit devices which require varying voltages at different areas. Furthermore, massive capacitors may require valuable real-estate for the power and ground TSVs.

Accordingly, there is a need in the industry to reduce the impedance in large arrays of capacitors (for example, massive capacitors) and to vary the voltage across multiple regions within large arrays of capacitors. There may be a need in the industry for routing flexibility as the power/ground lines going into the capacitors in these IPDs may be provided only from one side of a substrate (e.g., die side). Such IPDs may have TSVs, but they may only take power or ground from a first side to a second side (e.g., back side to front side) and then distribute the power or ground to the capacitors from the second side (e.g., front side). There is also a need in the industry to reduce the size of large arrays of capacitors without affecting the capacitance, to increase the amount of real estate within integrated circuit device arrangements.

Embodiments provided herein are directed to integrated circuits comprising capacitors (e.g., an array of capacitors) and methods of forming the same, which may result in reducing the impedance in large arrays of capacitors (e.g., massive capacitors). In some embodiments, the integrated circuits include a plurality of capacitors, each of which comprises three electrodes. In some embodiments, each capacitor may comprise at least three electrodes. In some embodiments, each capacitor may comprise three or more electrodes. The capacitors may directly provide access power and ground through a substrate comprising the capacitors, which thereby may replace the need for separate ground vias and power vias in other portions of the substrate comprising the capacitors.

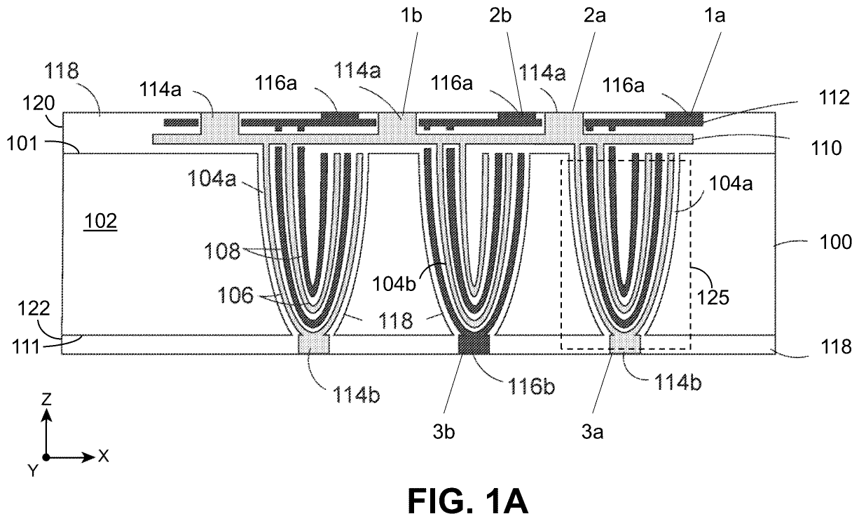

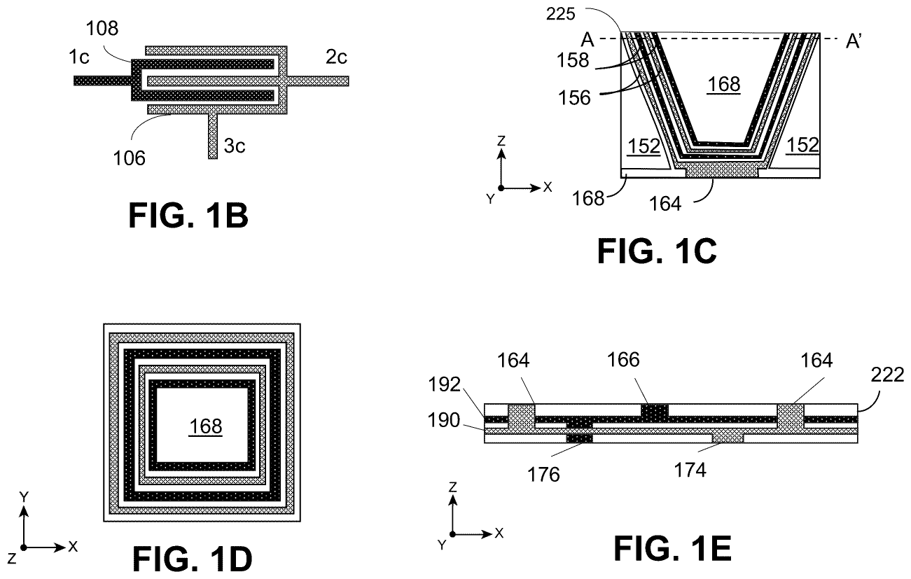

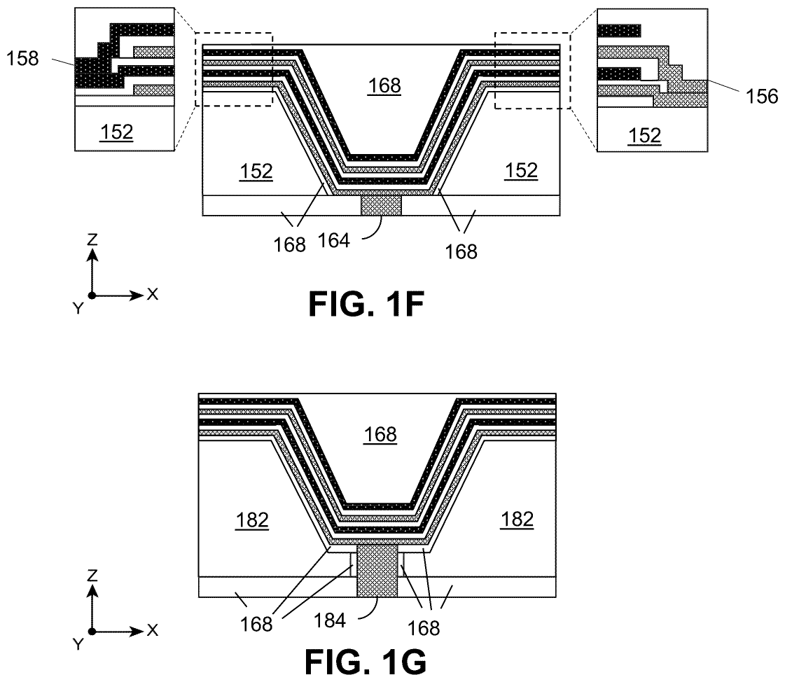

FIG. 1A is a schematic cross-sectional view of a component 100. The component 100 includes a plurality of capacitors 104a, 104b each comprising three electrodes (e.g., electrode 1a, electrode 2a, and electrode 3a or electrode 1b, electrode 2b, and electrode 3b). For example, capacitor 104a comprises three electrodes 1a, 2a, and 3a, and capacitor 104b comprises three electrodes 1b, 2b, and 3b. Electrode 3a and electrode 2a may be part of a ground via connection, and electrode 3b and electrode 2b may be part of a power via connection. Current may be passed through electrode 3a and electrode 2a or through electrode 3b and electrode 2b. A first of the three electrodes 1a of a first capacitor 104a may be coupled to ground or negative electrode and the second electrode 2a and a third electrode 3a of the three electrodes may be coupled to power or positive electrode. A first electrode 1b of the three electrodes of a second capacitor 104b may be coupled to power or positive electrode and the second electrode 2b and third electrode 3b of the three electrodes may be coupled to ground or negative electrode.

In some embodiments, electrode 1a of capacitor 104a may be coupled to a first voltage, and electrodes 2a and 3a of capacitor 104a may be coupled to each other and a second voltage. For example, the first voltage may be power or a positive voltage, or ground or a negative voltage. For example, the second voltage may be ground or a negative voltage, or power or a positive voltage. In some embodiments, there may be more than one positive voltages and negative voltages distributed across the component (e.g., component 100 or any component in various embodiments of the present disclosure). For example, one set of positive and negative electrodes and length of capacitors may determine the capacitance along with other structural parameters. For example, different groups of capacitors may be connected to different positive and negative voltages.

In some embodiments, electrode 1b of capacitor 104b may be coupled to a first voltage, and electrodes 2b and 3b of capacitor 104b may be coupled to each other and a second voltage. For example, the first voltage may be ground or negative voltage, or power or a positive voltage. For example, the second voltage may be power or positive voltage, or ground or negative voltage. In some embodiments, there may be more than one positive voltages and negative voltages distributed across the component (e.g., component 100 or any component in various embodiments of the present disclosure). For example, one set of positive and negative electrodes and length of capacitors may determine the capacitance along with other structural parameters. For example, different groups of capacitors may be connected to different positive and negative voltages.

Although FIG. 1A shows two capacitors 104a, and one capacitor 104b, there may be any suitable number of capacitors (e.g., 1, 3 or more capacitors 104a, 2 or more capacitors 104b), and numerically, more associated electrodes than what is shown in FIG. 1A. The component 100 may comprise an array of capacitors (e.g., in addition to the capacitors 104a, 104b shown along the X direction, there may be capacitors 104a, 104b in the Y direction). Although FIG. 1A shows two different type of capacitors (e.g., capacitor 104a can be supplied with power through contact 114b and ground through 114a, and capacitor 104b may be supplied with ground or negative voltage through 116b and power or positive voltage through 114a, there may be only one type of capacitor 104a or 104b in component 100. Additionally, it can be appreciated that what is shown in FIG. 1A could be replicated in much larger array with power and ground grouping as discussed herein to meet requirements of power management for a system or component.

The component 100 comprises a substrate 102. The substrate 102 comprises a first side 101 and a second side 111 opposite to the first side 101. The substrate 102 may comprise an amorphous material or a crystalline material. The substrate 102 may comprise a semiconductor material (e.g., silicon), a glass material, organic or inorganic material, any of the above-mentioned substrate materials in the present disclosure, or any other suitable substrate material.

In some embodiments, a first dielectric layer 120 is formed on the first side 101 of substrate 102. The first dielectric layer 120 comprises a dielectric material 118. As used herein, a dielectric material may comprise an oxide, nitride, silicon oxide, silicon nitride, silicon oxynitride, silicon carbonitride, any of the above-mentioned dielectric materials, or any other suitable dielectric material. The first dielectric layer 120 comprises a plurality of electrically conductive pads 114a, 116a extending through the first dielectric layer 120. The electrically conductive pads 114a, 116a may comprise a conductive material. As used herein, a conductive material may comprise metal (e.g., copper, aluminum, nickel, gold, etc.), semiconductor, polysilicon, doped polysilicon, conductive oxides, transparent conductive oxide (TCO), or any other suitable conductive material.

In some embodiments, the first dielectric layer 120 has a redistribution layer further comprising a plurality of conductive layers 110, 112 formed in the first dielectric layer 120. The electrically conductive layers 110, 112 may comprise a conductive material. For example, the electrically conductive layer 110, 112 may be an electrically conductive metal layer. The plurality of conductive layers 110, 112 electrically couples the plurality of capacitors 104a, 104b to each other. Coupling the plates of the capacitors 104a, 104b together provides improved distribution of power and ground to and from each of the plurality of capacitors 104a, 104b, thereby reducing overall impedance in the massive capacitor or capacitor array. The electrically conductive layers 110, 112 and conductive pads 114a, 116a of the redistribution layer may be shown in a same cross-sectional view but at different distances along the Y-axis. For example, conductive pads 114a and conductive layer 110 may be at one distance along the Y-axis, and the conductive pads 116a and conductive layer 112 may be at another distance along the Y-axis (behind the conductive pads 114a and conductive layer 110).

In some embodiments, groups of capacitors 104a, 104b may be coupled together through the redistribution layers (e.g., conductive layers are patterned to electrically couple groups of capacitors) to enable capacitors with specific effective capacitances. For example, in a massive capacitor, an array of capacitors may be uniformly formed across a substrate (e.g., wafer in a wafer level process). The capacitors may have similar capacitance and density per unit area. These capacitors may be grouped together through a redistribution layer to provide capacitance value based on design requirements. For example, several different groups of capacitors may be connected through a redistribution layer, with each group providing capacitance value based on design requirements. For example, groups of capacitors (2, 3, 4, 5 or more capacitors) are connected in parallel providing an effective capacitance that is the sum of individual capacitance of the capacitors. In this way, different capacitances may be generated from groups of capacitors of the massive capacitor.

In some embodiments, the redistribution layer may further comprise fuse or anti-fuse components to electrically couple or separate groups of capacitors. The fuse or anti-fuse component may be used to electrically couple or separate groups of capacitors post-manufacturing of the capacitors and their routing. This may enable generating capacitors with having particular effective capacitances (e.g., groups of capacitors has effective capacitance as the sum of individual capacitances). In this way, different capacitances may be generated from groups of capacitors of the massive capacitor after manufacturing the component.

In some embodiments, a second dielectric layer 122 is formed on the second side 111 of the substrate 102. The second dielectric layer 122 may be similar to the first dielectric layer 120. The second dielectric layer 122 may comprise dielectric material 118 (e.g., same dielectric material used for first dielectric layer 120). In some embodiments, the second dielectric layer 122 may comprise a different dielectric material than the first dielectric layer. The second dielectric layer 122 comprises a plurality of electrically conductive pads 114b, 116b extending through the second dielectric layer 122. The electrically conductive pads 114b, 116b may be similar to electrically conductive pads 114a, 116a.

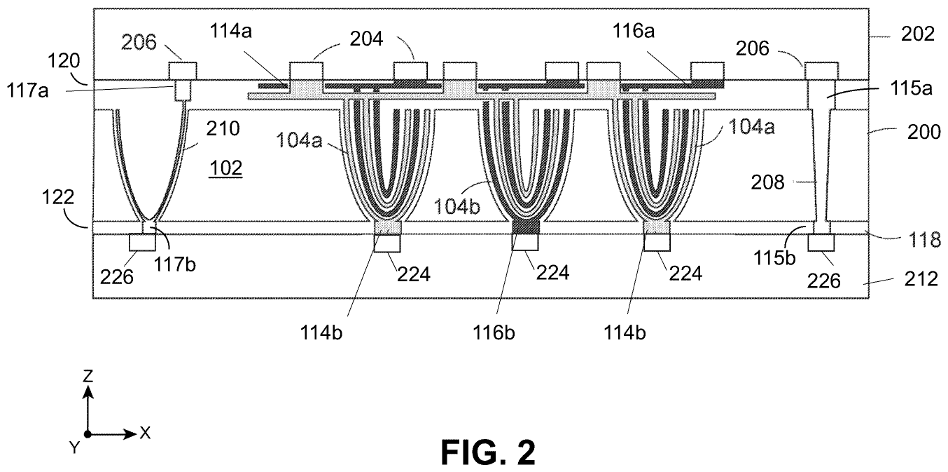

In some embodiments, the second dielectric layer may be a redistribution layer further comprising a plurality of conductive layers. For example, the second dielectric layer 222 of FIG. 1E comprises a plurality of conductive layers 190, 192, and may be applied to any of the embodiments of the present disclosure (e.g., used in place of second dielectric layer 122 in FIGS. 1A and 2). Additional description of FIG. 1E can be found below in the detailed description of FIG. 1E.

The component 100 comprises a plurality of capacitors 104a, 104b, each formed in an opening that extends from the first side 101 of the substrate 102 to the second side 111 of the substrate 102. In some embodiments, an opening does not extend through a substrate. In some embodiments, the term “opening” may refer to a cavity. In some embodiments, a plurality of capacitors may be formed in an opening or a cavity that extends at least partially from the first side of the substrate towards the second side of the substrate. In some embodiments, “openings” may in the substrate may include an opening that is less than the thickness of the substrate and conductive pads 114b and 116b may partially penetrate the substrate 102 to contact an outermost plate of a capacitor that is disposed in the substrate 102. For example, an outermost plate of the capacitor is disposed within the body of the substrate 102, instead of being exposed to the second dielectric layer 122. The opening in the substrate 102 and layers deposited in the opening (e.g., layers of the capacitor 104a or 104b, dielectric material 118, and conductive layers 106 and 108) may be any suitable shape. For example, FIG. 1A shows a cone-type shape, and FIG. 1C shows a trapezoidal-type shape. Additional description of FIG. 1C can be found below in the detailed description of FIG. 1C. The opening can have any three-dimensional shape, including for example, a cylinder, a cube, a prism, or a frustoconical shape, among others. The inner surface of the opening can extend from the first substrate through the substrate at any angle (e.g., at an angle between about 0 and 80 degrees to the horizontal plane defined by the first surface, or greater than about 80 degrees). In some embodiments, the inner surface of the opening can extend from the first substrate through the substrate at an angle close to 90 degrees, i.e. almost vertical sidewalls. The inner surface can have a constant slope or a varying slope. In some embodiments, a width of the opening may be at least about 1 micron, greater than about 50 microns, greater than about 75 microns, greater than about 100 microns, less than about 750 nm, less than about 500 nm. In some embodiments, a depth of the opening may be about 10 microns, greater than about 10 microns, less than about 10 microns, less than about 20 microns, about 5 microns, less than about 5 microns, greater than about 5 microns. In some embodiments, the capacitors 104a, 104b may extend through a plurality of openings. In some embodiments, a spacing between capacitors may be about 10 nm to 100 nm, less than about 50 nm, less than about 25 nm, less than about 10 nm, more than about 100 nm, about 0.5 micron to 1 micron, less than about 0.5 micron, more than about 1 micron. In some embodiments, a spacing between one group of capacitors to another group of capacitors may be tens or hundreds of microns. The shape chosen for the capacitor structure may be designed to give the electrodes the surface area(s) desired for the capacitor size to be implemented in the design. Although the embodiments shown in the figures generally have the power and ground electrode surfaces to be similar in size, variations may be employed and be within the concepts presented in the various embodiments herein.

Each capacitor 104a, 104b may have first and second plates (e.g., conductive layers 106 and 108) extending along inner surface of the opening in the substrate 102, and each plate separated from at least one adjacent plate by one or more dielectric layers (e.g., dielectric material 118, or Oxide-Nitride-Oxide (ONO) layers e.g., a few nm each of oxide, nitride, oxide layers). A portion of the opening not occupied by first and second pairs of plates may be filled with a dielectric material 118. The capacitors 104a, 104b comprise two conductive layer 106 to form a first pair of plates and two conductive layer 108 to form a second pair of plates. However, any suitable number of conductive layers 106 and 108 may be used. For example, a capacitor may comprise one conductive layer 106 to form a first plate, another conductive layer 108 to form a second plate and at least one dielectric separation layer (e.g., dielectric material 118) separating conductive layers 106 and 108. A capacitor may comprise three or more conductive layers 106 to form three or more first plates and three or more conductive layers 108 to form three or more second plates.

Each of the plurality of capacitors 104a, 104b may be coupled to an electrically conductive pad 114a, 116a of the first dielectric layer 120 and an electrically conductive pad 114b, 116b of the second dielectric layer 122. For example, a first capacitor 104a is coupled to an electrically conductive pad 114a or 116a of the first dielectric layer 120 and an electrically conductive pad 114b of the second dielectric layer 122. As another example, a second capacitor 104b is coupled to an electrically conductive pad 114a or 116a of the first dielectric layer 120 and an electrically conductive pad 116b of the second dielectric layer 122. The outermost plate (e.g., conductive layer) of the capacitors 104a, 104b is coupled to the conductive pads 114b or 116b of the second dielectric layer 122 and the conductive pads 114a, 116a of the first dielectric layer 120, forming a conductive via through the substrate (e.g., to pass power or ground through the substrate).

In some embodiments, the first dielectric layer 120, the second dielectric layer 122, and the insulating layer (e.g., layer between substrate 102 and conductive layer of capacitor) and dielectric layers of the capacitors 104a, 104b (e.g., dielectric layer between conductive layers of the capacitor) may be formed of a same material (e.g., dielectric material 118). In some embodiments, an insulating layer may not separate a conductive layer of the capacitor and the substrate (e.g., substrate comprises an insulating material, substrate comprising a glass material). In some embodiments, the first dielectric layer 120, the second dielectric layer 122, and dielectric layers within the component 100 may be formed of different dielectric materials. The insulating layer and dielectric layers of the capacitors 104a, 104b (e.g., comprising dielectric material 118) may comprise any suitable dielectric material.

In some embodiments, a first integrated circuit device is attached to or formed on the first dielectric layer. For example, FIG. 2 shows a first integrated circuit device 202 attached to or formed on the first dielectric layer 120. Additional description of FIG. 2 can be found below in the detailed description of FIG. 2.

FIG. 1B is a schematic diagram a capacitor with three electrodes, in accordance with some embodiments of the disclosure. The reference to right and left below refers to the frame of reference shown in FIG. 1B to 1F. FIG. 1B shows a schematic diagram of a capacitor comprising three electrodes (electrode 1c, electrode 2c, and electrode 3c). Current may be passed through electrode 2c and electrode 3c. The schematic diagram of capacitor of FIG. 1B may be similar to a schematic diagram of the first capacitor 104a of FIG. 1A comprising electrodes 1a, 2a, and 3a. For example, the electrodes 1c, 2c, and 3c may correspond to conductive pads 116a, 114a, and 116b respectively of FIG. 1A. However, instead of conductive pad 114a being on a left side of a capacitor connected to a left portion of the conductive layers 106, the conductive pad 114a may be on a right side of capacitor 104a connecting to the conductive layers 106 on a right side of the capacitor 104a. Also, instead of conductive pad 116a being on a right side of the capacitor 104a, the conductive pad 116a may be on a left side of the capacitor 104a connecting to the conductive layers 108 of capacitor 104a. In addition, the capacitor of FIG. 1B also includes an additional capacitor plate (e.g., a pair of plates connected to a first electrode 1c, three plates connected to a second electrode 2c and an outermost of the three plates connected to electrode 3c). For example, FIG. 1F shows conductive layers 158 (e.g., corresponding to conductive layers 108) connected on a left side of the capacitor, and conductive layer 156 (e.g., corresponding to conductive layers 106) connected on the right side of the capacitor. The conductive layers 158 may also be connected to a conductive pad 116a placed on a left side of the capacitor 104a, and the conductive layers 106 may be connected to a conductive pad 114a placed on a right side of capacitor 104a. An additional dielectric layer and conductive layer 106 may be deposited on the topmost conductive layer 108 of capacitor 104a before a dielectric layer fills the opening that the capacitor 104a is formed in, and the additional conductive layer 106 may comprise the third plate of the capacitor of FIG. 1B.

FIG. 1C is a schematic cross-sectional view of a portion 225 of a capacitor. Portion 225 of the capacitor includes a substrate 152, dielectric material 168, conductive pad 164, first conductive layer 156, and second conductive layer 158 that may correspond to (e.g., be the same as or similar to) the substrate 102, dielectric material 118, conductive pad 114b, first conductive layer 106, and second conductive layer 108 of FIG. 1A, respectively. However, FIG. 1A shows a portion 125 of the capacitor 104a with conductive and dielectric layers having a cone-type shape, following a shape of an opening in the substrate 102, and the portion 225 shows a trapezoid-type shape. Although two shapes are shown in FIGS. 1A and 1C, any suitable shape may be used (e.g., opening having a sidewall at a different angle, a curved sidewall, vertical sidewall with flat or curved bottom, wider or narrower opening, any type of suitable etched or patterned opening).

FIG. 1D is a schematic of another cross-sectional view of the portion of the capacitor. For example, the cross-sectional view is along the line A to A′ of FIG. 1C showing a horizontal cross section instead of a vertical cross section of a capacitor. Although FIG. 1D shows a rectangular shape, the shape may be any suitable shape (e.g., having a narrower or wider width, shorter or longer length, a square, circle, oval, regular shape, irregular shape, or any other suitable shape).

FIG. 1E is a schematic cross-sectional view of a second dielectric layer 222 of a component. The second dielectric layer 222 comprises a plurality of conductive layers 190, 192 and conductive features 164, 166, 174, and 176. The electrically conductive layers 190, 192 may be similar to the electrically conductive layers 110, 112 of FIG. 1A. The plurality of conductive layers 190, 192 may electrically couple the plurality of capacitors 104a, 104b to each other. The conductive pads 164, 166 may be correspond to (e.g., be similar to) conductive pads 114a, 116a of FIG. 1A. However, the conductive pads 164, 166 are connected to a respective conductive line, and the respective conductive line may include conductive pads 174, 176 to couple to a power or a ground connection. The conductive pads 164, 166, 174, and 176 may comprise a conductive material.

FIG. 1F is a schematic cross-sectional view of a portion of a capacitor. The capacitor shown in FIG. 1F is similar to or the same as the capacitor shown in FIG. 1C, except connections to the conductive layers 158 and 156 are shown in insets to the left and right of the capacitor. In some embodiments, the connections to the conductive layers 156 are to the left of the capacitor, and the connections to the conductive layers 158 are to the right of the capacitor in a cross-sectional view. FIG. 1F may show electrically conductive layers at a distance along the Y-axis.

FIG. 1G is a schematic cross-sectional view of a portion of a capacitor. The capacitor shown in FIG. 1G is similar to the capacitor shown in FIG. 1F, except a conductive pad disposed in the second dielectric layer is also disposed in a portion of the substrate 182 to make an electrical connection to an outermost plate of the capacitor. Substrate 182 may correspond to (e.g., be the same as or similar to) the substrate 152 except substrate 182 includes an opening or cavity does not extend from one side of substrate 182 to another side of substrate 182. The second dielectric layer (e.g., dielectric material 168) may be formed or disposed on the substrate 182. The conductive pad 184 may be disposed in the second dielectric layer and a portion of the substrate 182. In some embodiments, a dielectric layer (e.g., dielectric material 168) may be disposed between the conductive pad 184 and portions of the substrate 182. For example, a dielectric layer (e.g., dielectric material 168) may surround portions of the conductive pad 184 to separate (e.g., electrically insulate) the conductive pad 184 from the substrate 182.

In some embodiments, the connections shown in the insets on the left and right side of a capacitor may have a same type of configuration. For example, a capacitor may comprise five electrodes. The capacitor may have two electrodes or connections to conductive layer 158 on the left and right of the capacitor (e.g., at a same Y-axis distance). In a perpendicular cross section (e.g., at a same X-axis distance), the capacitor may have another two electrodes or connections to conductive layer 158 to left and right of the capacitor. The capacitor may have a fifth electrode connection to the outermost conductive layer of the capacitor (e.g., conductive pad 164). The configurations described in relation to FIG. 1F can be applied to any of the pass through capacitors described in the present disclosure (e.g., capacitors of FIGS. 1A-1E, 2 and 3).

In some embodiments, a first dielectric layer of a redistribution layer (e.g., dielectric material 168) is formed on top of the conductive layer 158, and a via may be formed (e.g., an opening etched through the first dielectric layer to the conductive layer 158 and filled with a conductive layer (e.g., conductive layer 110)). In some embodiments, the conductive layer 110 may be patterned and another dielectric layer (e.g. dielectric material 168, or dielectric material 118 of FIG. 1A) may be formed on the conductive layer 110. A dielectric layer (e.g., dielectric material 168) may be deposited on top of the conductive layer 156, and a via may be formed (e.g., an opening etched through the dielectric material 168 to the conductive layer 156 and filled with a conductive layer (e.g., conductive layer 112). In some embodiments, the conductive layer 112 may be patterned, and another dielectric layer (e.g. dielectric material 168, or dielectric material 118 of FIG. 1A) may be formed on the conductive layer 112. Openings may be formed or etched through a dielectric layer to a conductive layer (e.g., conductive layer 110 or conductive layer 112) and filled with a conductive layer to form a conductive pad (e.g., conductive pad 114a or conductive pad 116a in FIG. 1A).

FIG. 2 is a schematic cross-sectional view of an integrated component 200 with capacitors (e.g., capacitors 104a and capacitor 104b) and vias integrally coupled to two devices (e.g., first device 202 and second device 212). Advantageously, the integrated component 200 can pass signals or power or ground from one component to another component (e.g., from one device 202 to another device 212) while also acting as a massive capacitor.

In some embodiments, the component 200 is similar to the component 100 of FIG. 1A, except the component 200 includes a via 208, conductive pads 115a and 115b, a via 210, and conductive pads 117a, 117b. For example, the vias 208 and 210 are disposed in the substrate 102, conductive pads 115a and 117a are disposed in the first dielectric layer 120, and conductive pads 115b and 117b are disposed in the second dielectric layer 122.

The via 208 may comprise a conductive layer comprising a conductive material. The via 208 may defined by an opening through the substrate 102. For example, the substrate 102 may be patterned or etched and filled with a conductive layer. The via 208 or conductive layer may carry a signal, power, or ground. The via 208 may be coupled to a third electrically conductive pad (e.g., conductive pad 115a) extending through the first dielectric layer 120 and a second electrically conductive pad (e.g., conductive pad 115b) extending through the second dielectric layer 122.

The via 210 may comprise a conductive layer comprising a conductive material. The via 210 or conductive layer may carry a signal, power, or ground. The via 210 may be defined by an opening through the substrate 102. For example, the substrate 102 may be patterned or etched, and a conductive layer may be deposited in the opening, conforming to a shape of the opening. A dielectric layer may be deposited on the conductive layer and used to fill the opening. In some embodiments, the dielectric layer 120 further comprises the dielectric material 118 used to fill the opening. In some embodiments, the dielectric layer used to fill the opening may be a separate layer and may comprise a same or different material than the first dielectric layer 120. The via 210 or conductive layer may be coupled to a third electrically conductive pad (e.g., conductive pad 117a) extending through the first dielectric layer 120 and a second electrically conductive (e.g., conductive pad 117b) extending through the second dielectric layer 122.

In some embodiments, the via 210 is defined in an opening through the substrate 102 using a similar process (e.g., etch) to form the openings corresponding to capacitors 104a, 104b. For example, the via 210 may be formed by utilizing the same process steps for forming a capacitor (e.g., etch opening, conductive layer deposition, dielectric layer deposition). The via may comprise one or more conductive layers shorted together (e.g., patterned or formed so that there is no intervening dielectric layer between the conductive layer). For example, the via may comprise one conductive layer 106 or 108, two conductive layers (e.g., pair of conductive layers 106 shorted together, one of the conductive layers 106 shorted to one of the conductive layers 108), three conductive layers (pair of conductive layers 106 shorted together to one of the conductive layers 106, pair of conductive layers 108 shorted to one of the conductive layers 106), or four conductive layers (pair of conductive layers 106 and 108 shorted together). By generating the via 210 utilizing process steps for forming the capacitor, additional process steps may not be required for forming a via 210.

Although two vias are shown, the component 200 may include any suitable number of vias (e.g., one, three or more). Although two types of vias are shown, the component may include vias of any type (e.g., all of one type, other different types of vias, etc.).

The first device 202 may be an integrated circuit device. The first device 202 may be a passive or an active device or chip. In some embodiments, the first device 202 is face down (e.g., a front side or an active side of the first device 202 is facing the component 200). The first device 202 may be provided and attached to the redistribution layer of the component 200. In some embodiments, the first device 202 is formed on the redistribution layer of the passive component 200. The first device 202 comprises conductive pads 204, 206 comprising a conductive material.

In some embodiments, the component 200 may have a different orientation relative to the devices. For example, the component 200 may be flipped so that the conductive pads 114b, 116b face a first device (e.g., similar to first device 202 but with different conductive pad configuration) may be attached to or formed on the second dielectric layer 122 (or redistribution layer 222 of FIG. 1E). A second device (e.g., similar to second device 212 but with different conductive pad configuration) may be attached to or formed on the redistribution layer (or first dielectric layer 120).

The second device 212 may be an integrated circuit device. The second device 212 may be a passive, an active chip, or a substrate (e.g. silicon or glass interposer, organic interposer, reconstituted wafer, PCB, fanout wafer level package, etc.). In some embodiments, the second device 212 is provided and attached to the dielectric layer 122. For example, the second device 212 may be a substrate and may be attached via flip bonding to the component 200. In some embodiments, the second device 212 is formed on the dielectric layer 122. The first device 202 may be an active or passive device. The first device 202 comprises conductive pads 204, 206 comprising a conductive material. In some embodiments, the second dielectric layer 122 comprises a redistribution layer (e.g., second dielectric layer 222 of FIG. 1E), and the second device 212 may be attached or formed on the redistribution layer.

In some embodiments, the first device 202 is electrically connected to the component 200. The first device 202 may be electrically coupled to at least one of the electrically conductive pads (e.g., conductive pads 114a, 116a) of the first dielectric layer 120. For example, the first device 202 comprises conductive pads 204 that are electrically connected to conductive pads 114a and 116a, and conductive pads electrically connected to conductive pads 115b, 117b. In some embodiments, the conductive pads 204 are directly bonded to the conductive pads 114a, 116a (e.g., for power and ground), and the conductive pads 206 are directly bonded to the conductive pads 117a, 115a (e.g., for signals). The first device 202 may comprise a dielectric layer that the conductive pads 204, 206 are disposed in, and the first dielectric layer 120 may form direct dielectric bonds to the dielectric layer of first device 202. The first device 202 may be directly hybrid bonded to the component 200. In some embodiments, the conductive pads 204, 206, 114a, 116a, may be used for power, ground, or signal(s). In some embodiments, the conductive pads 204, 206 of the first device may be electrically coupled to the conductive pads 114a, 116a, 206 of the component 200 using solder, conductive adhesive, or any suitable technique.

In some embodiments, the second device 212 is electrically connected to the component 200. The second device 212 may be electrically coupled to at least one of the electrically conductive pads (e.g., conductive pads 114b, 116b, 115b, 117b) of the second dielectric layer 122. For example, the second device 212 comprises conductive pads 224 electrically connected to conductive pads 114b and 116b, and conductive pads 226 electrically connected to conductive pads 115b and 117b. In some embodiments, the conductive pads 224 are directly bonded to the conductive pads 114b, 116b (e.g., for power and ground), and the conductive pads 226 are directly bonded to the conductive pads 115b, 117b (e.g., for signals). The second device 212 may comprise a dielectric layer that the conductive pads 224, 226 are disposed in, and the second dielectric layer 122 may form direct dielectric bonds to the dielectric layer of second device 212. The second device 212 may be directly hybrid bonded to the component 200. In some embodiments, the conductive pads 224, 226, 114b, 116b, may be used for power, ground, or signal(s). In some embodiments, the conductive pads 224, 226 of the second device 212 may be electrically coupled to the conductive pads 114b, 116b, 115b, 117b of the component 200 using solder, conductive adhesive, or any suitable technique. For example, connection of conductive pads of the component 200 to first device 202 and second device 212 may be through conductive materials such as a fusible metal, e.g., solder, tin, or a eutectic mixture including a plurality of metals, a wettable material, e.g., copper or other noble metal or non-noble metal.

In some embodiments, the capacitors 104a, 104b can directly provide access power and ground through the electrically conductive pads 114b, 116b in the second dielectric layer 122 and directly provide this power and ground to the integrated component 200 to the integrated circuit device 202, thereby replacing the need for separate ground and power vias. Advantageously, the size of large arrays of capacitors (e.g., massive capacitors) can be reduced. By directly accessing power or ground, the distance that power or ground has to travel to the capacitor 104a, 104b (and/or the integrated circuit device) may be reduced, thereby reducing impedance in large arrays of capacitors. Each of the plurality of capacitors can be coupled to a distinct power or ground connection, thereby providing an arrangement where each of the capacitors can carry varying voltages which allows for multiple voltage regions to be present in massive capacitors. This allows for a massive capacitor that can provide capacitance to a plurality of integrated circuit devices with different power and ground requirements.

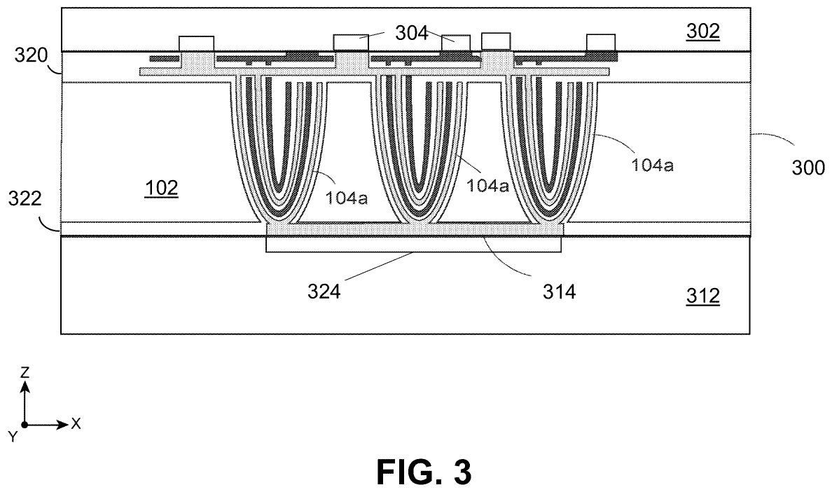

FIG. 3 is a schematic cross-sectional view of an integrated component 300 with capacitors 104a integrally coupled to two devices (e.g., first device 302 and second device 312). In some embodiments, the component 300 is similar to the component 100 of FIG. 1A, except the component 300 includes multiple capacitors of a same type (e.g., capacitors 104a) that are electrically grouped together on one conductive pad. A first dielectric layer 320 may be similar to the first dielectric layer 120, and second dielectric layer 322 may be similar to second dielectric layer 122. A first device 302 may be similar to the first device 202 of FIG. 2. For example, first device 302 comprises conductive pads 304 corresponding to conductive pads 204 of first device 202 of FIG. 2. Second device 312 may be similar to the second device 212 of FIG. 2, except that second device 312 may be electrically connected to multiple capacitors that are electrically grouped together via one electrically conductive pad 314 of the second dielectric layer 322. For example, second device 312 comprises a conductive pad 324 which may correspond to a conductive pad 224 of FIG. 2. However, the conductive pad 324 may be connected to multiple capacitors 104a instead of the conductive pad 224 being connected to one capacitor 104a of FIG. 2. Power may be supplied to the multiple capacitors 104a through conductive pad 314 of the second dielectric layer 322. For example, an outermost conductive layer (e.g., plate) of each capacitor 104a is electrically connected to the conductive pad 314. In some embodiments, ground may be supplied to grouped capacitors 104a through a conductive layer of the redistribution layer (e.g., first dielectric layer 320) through another pass thru capacitor (e.g., an adjacent capacitor or any capacitor connected through a conductive layer of the redistribution layer such as capacitor 104b of FIG. 2 or multiple capacitors 104b connected to one conductive pad as described below).

Although FIG. 3 shows the component 300 including only capacitors 104a, in some embodiments the component 300 may alternatively or additionally include multiple capacitors 104b that are electrically grouped together. For example, the component 300 may include multiple capacitors 104b, and an outermost conductive layer (e.g., plate) of the capacitors 104b may be electrically connected a conductive pad to connect to multiple capacitors (e.g., capacitors 104b). Ground may be supplied to the capacitors 104b through a conductive pad of the second dielectric layer 322. For example, an outermost conductive layer (e.g., plate) of each of the capacitors 104b is electrically connected to the conductive pad. In some embodiments, power may be supplied to grouped capacitors 104b through another pass thru capacitor (e.g., an adjacent capacitor, capacitor 104a of FIGS. 2, multiple capacitors 104a of FIG. 3), connected through a conductive layer of a redistribution layer, and a grouping of capacitors may comprise the multiple capacitors 104b and the capacitor 104a or multiple capacitors 104a that provide the power connection. In some embodiments, a grouping of capacitors may be only the multiple capacitors 104b, and a via may supply a power to a conductive layer of redistribution layer.

Although FIG. 3 shows a component 300 without vias, in some embodiments the component 300 may include one or more vias (e.g., via 208 and via 210 of FIG. 2). For example, the vias may carry a signal, ground, or power. The first device 302 and second device 312 may have corresponding bonding pads (e.g., bonding pads 206 of the first device and bonding pads 226 of the second device).

Although FIG. 3 shows a grouping of three capacitors 104a to one conductive pad 314 of the second dielectric layer 322, any suitable number of capacitors may be used (e.g., 2, 3, 5 or more). Although FIG. 3 shows a grouping of capacitors 104a, any suitable type of capacitors may be used (e.g., capacitor 106a, capacitors with a different number of plates or electrodes).

In some embodiments, the second dielectric layer 322 may further comprise a redistribution layer (e.g., similar to second dielectric layer 222). In some embodiments, the configuration of component 300 may be flipped (e.g., second dielectric layer 322 and conductive pad 314 faces a first device). For example, a device (e.g., corresponding to first device 302 but may have a different pad distribution) may be attached or formed onto the second dielectric layer 322 or redistribution layer (e.g., second dielectric layer 322 of FIG. 1A). A second device (e.g., corresponding to second device 312 but may have a different pad distribution) may be attached or formed on the first dielectric layer 120 or redistribution layer.

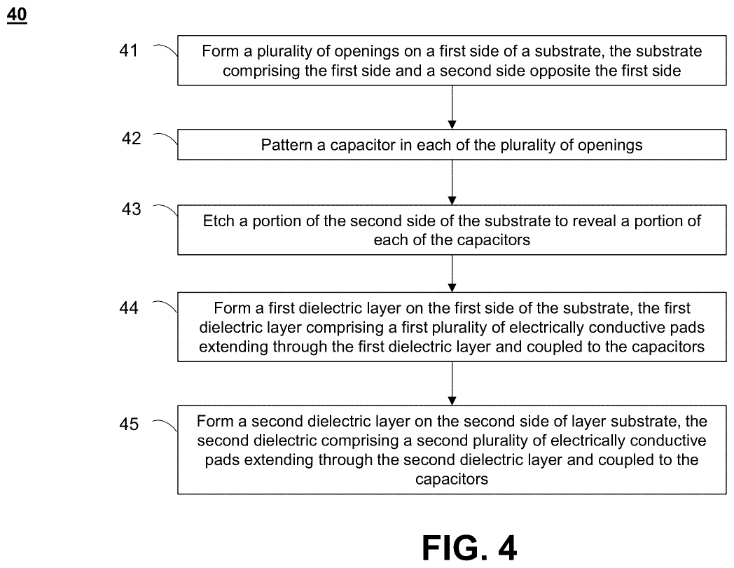

FIG. 4 is a flowchart of illustrative steps involved in forming a component. In some embodiments, a method 40 of forming an integrated component (e.g., component 200 of FIG. 2) for a plurality of capacitors each comprising three electrodes is provided.

At block 41, the method 40 includes forming a plurality of openings on a first side of a substrate, the substrate comprising the first side and a second side opposite the first side. For example, a plurality of openings (e.g., cavities) may be formed on the first side 101 of the substrate 102. The openings may be in any suitable shape (e.g., cone-like openings of FIG. 1A, trapezoidal-shaped openings of FIG. 2, etc.).

At block 42, the method 40 includes patterning a capacitor in each of the plurality of openings. Patterning a capacitor may comprise (1) forming a dielectric layer or insulating layer in the opening, (2) forming a conductive layer (e.g., first plate) on the dielectric layer in the opening, (3) forming a dielectric layer on the conductive layer in the opening, (4) forming a conductive layer (e.g., second plate) on the second dielectric layer in the opening, (5) in some embodiments, repeating steps (1)-(4) at least one more time to form additional first and second plates, and (6) forming a third dielectric layer on the second conductive layer in the opening, the third dielectric layer filling the opening. In some embodiments, the dielectric layer separating conductive layers may be one or more dielectric layers (e.g., dielectric material 118, ONO layers).

In some embodiments, the method 40 may comprise forming a first conductive layer, a second conductive layer, and a plurality of dielectric layers separating the first and second conductive layers in each of the plurality of capacitors. The method 40 may comprise coupling the first conductive layer to a first electrically conductive pad of the first dielectric layer forming the first electrode, and coupling the second conductive layer to a second electrically conductive pad of the first dielectric layer forming the second electrode. More generally, coupling a conductive layer to a conductive pad may comprise exposing a portion of a conductive layer and forming an electrically conductive pad to contact or physically touch the exposed portion of the conductive layer. More generally, coupling a conductive layer to a conductive pad may comprise exposing a portion of the conductive pad and forming a conductive layer to contact or physically touch the exposed portion of the conductive pad. In some embodiments, the term coupling may mean directly or indirectly connecting (e.g., physically or electrically connecting) to one another. In some embodiments, the term “coupled” to one another may mean directly or indirectly connected (electrically or physically) to one another, directly or indirectly touching or in contact with one another, or electrically conductive with minimal or low impedance between one another.

At block 43, the method 40 includes etching a portion of the second side of the substrate to reveal a portion of each of the capacitors. For example, a portion of the substrate 182 of FIG. 1G may be patterned or etched to reveal a portion of an outermost conductive layer of the capacitor that may be filled with a conductive layer (e.g., portion of conductive pad 184 disposed in a portion of the substrate 182). In some embodiments, the substrate may be back grinded or polished back to the second surface to reveal a portion of each of the capacitors. For example, the substrate 102 may be back grinded or polished to the second side 111 of the substrate 102 to reveal a portion (e.g., portion of the outermost conductive layer 106) of each of the capacitors.

At block 44, the method 40 includes forming a first dielectric layer on the first side of the substrate, the first dielectric layer comprising a first plurality of electrically conductive pads at least partially extending through the first dielectric layer and coupled to the capacitors. In some embodiments, the conductive pads may extend through the first dielectric layer and be coupled to the capacitors. The method 40 may further comprise forming a plurality of conductive layers in the first dielectric layer, the plurality of conductive layers electrically coupling the plurality of capacitors to each other. Forming the plurality of conductive layers or at least a group of the plurality of conductive layers in the first dielectric layer may comprise forming a third conductive layer electrically coupling the first conductive layer of each capacitor or each capacitor of at least a group of capacitors, and forming a fourth conductive layer electrically coupling the second conductive layer of each capacitor or each capacitor of at least the group of capacitors.

At block 45, the method 40 includes forming a second dielectric layer on the second side of layer substrate, the second dielectric comprising a second plurality of electrically conductive pads at least partially extending through the second dielectric layer and coupled to the capacitors. In some embodiments, the second plurality of electrically conductive pads may extend through the second dielectric layer and be coupled to the capacitors. The outermost conductive layer of each capacitor comprises either the first conductive layer or the second conductive layer, and the method 40 may further comprises coupling the outermost conductive layer of each capacitor to a first electrically conductive pad of the second dielectric layer forming the third electrode of the capacitor. In some embodiments, the second plurality of electrically conductive pads may extend through the second dielectric layer and partially through the substrate to be coupled to the capacitors. For example, the outermost conductive layer of each capacitor 104a, 104b may not be exposed at a second side of the substrate (e.g., second side 111 of substrate 102 in FIG. 1A), and an electrically conductive pad (e.g., conductive pad 184 of FIG. 1G) extends through the second dielectric layer (e.g., dielectric material 168) and partially through the substrate (e.g., substrate 182 in FIG. 1G) to be electrically coupled to the outermost conductive layer of each capacitor through a portion of the substrate.

In some embodiments, the method 40 may comprise forming a via in the substrate, wherein the via comprises a conductive layer. The method 40 may comprise coupling the conductive layer to a third electrically conductive pad extending through the first dielectric layer and a second electrically conductive pad extending through the second dielectric layer.

In some embodiments, the method 40 may comprise coupling the plurality of pass-through capacitors to one of the electrically conductive pads of the second dielectric layer.

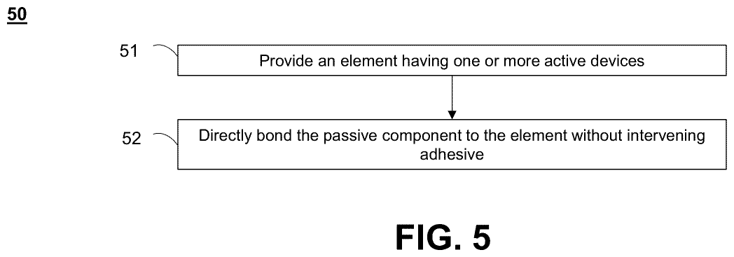

FIG. 5 is a flowchart of illustrative steps involved in forming an integrated component, in accordance with some embodiments of the disclosure. Forming an integrated component may comprise attaching a component to an element (e.g., a device or chip). For example, the component may be component 100, 200, or 300, and the element may be a first device 202, first device 302, second device 212, or second device 312. In some embodiments, one of the first devices 202/212 and second devices 302/312 can be a substrate (e.g. silicon or glass interposer, organic interposer, PCB, fanout wafer level package (FOWLP), reconstituted wafer, etc.). The substrate may be attached to the component using flip chip bonding.

At block 51, the method 50 includes providing an element having one or more active devices. In some embodiments, the element may be a passive element (e.g., passive device).

At block 52, the method 50 includes directly bonding the component to the element without intervening adhesive. For example, the component may be hybrid bonded to the element (e.g., direct bonding conductive pads and dielectric layers). In some embodiments, the component may be attached to the element (e.g., via solder or some other suitable technique).

In some embodiments, the method 50 comprises attaching a second integrated circuit device on the second dielectric layer and electrically coupling the second integrated device to at least one of the electrically conductive pads of the second dielectric layer. The second dielectric layer may be a redistribution layer further comprising a plurality of conductive layers formed in the second dielectric layer. The plurality of conductive layers may electrically couple the plurality of capacitors to each other and form the third electrode of each capacitor.

In some embodiments, the method 50 comprises forming a direct bonding interface or forming a hybrid bonding interface. The direct bonding interface or the hybrid bonding interface may be formed directly between the first dielectric layer and a first integrated circuit device.

In some embodiments, any of the components (e.g., components 100, 200, 300) mentioned above and in the present disclosure may be a passive component. In some embodiments, any of the components (e.g., components 100, 200, 300) mentioned above and in the present disclosure may further comprise an active device, and may be an active component. In some embodiments, a method 40 of forming a component may further include forming an active device, and may be a method of forming an active component.

In some embodiments, a method of forming an integrated active component may comprise providing an element having one or more active devices, and directly bonding an active component to the element without intervening adhesive. For example, an active component may be directly hybrid bonded to the element. In some embodiments, an element may be a passive device.

In some embodiments, any of the capacitors mentioned above (e.g., capacitor 104a, 104b) and in the present disclosure may be pass-through capacitors. In some embodiments, any of the capacitors mentioned above (e.g., capacitor 104a, 104b) and in the present disclosure may be formed in an opening that extends at least partially from a first side towards a second side of a substrate. In some embodiments, any of the capacitors mentioned above (e.g., capacitor 104a, 104b) and in the present disclosure may be formed in an opening that extends through the first side towards the second side of a substrate. In some embodiments, any of the capacitors mentioned above (e.g., capacitor 104a, 104b) and in the present disclosure may have at least three electrodes, and although the electrodes may be described as being coupled to power and ground, may be coupled to a first voltage (e.g., positive voltage) and a second voltage (e.g., negative voltage).

Generally, directly bonding the surfaces includes preparing, aligning, and contacting the surfaces. Examples of dielectric material layers include silicon oxide, silicon nitride, silicon oxynitride, and silicon carbonitride. Preparing the surfaces may include smoothing the respective surfaces to a desired surface roughness, such as between 0.1 to 3.0 nm RMS, activating the surfaces to weaken or open chemical bonds in the dielectric material, and terminating the surfaces with a desired species. Smoothing the surfaces may include polishing the first and second substrates using a CMP process. Activating and terminating the surfaces with a desired species may include exposing the surfaces to radical species formed in a plasma. The bond interface between the bonded dielectric layers can include a higher concentration of materials from the activation and/or last chemical treatment processes compared to the bulk of the bonding layers. For example, some embodiments that utilize a nitrogen plasma for activation, a nitrogen concentration peak can be formed at the bond interface. In some embodiments, the nitrogen concentration peak may be detectable using secondary ion mass spectroscopy (SIMS) techniques. In various embodiments, for example, a nitrogen termination treatment (e.g., exposing the bonding surface to a nitrogen-containing plasma) can replace OH groups of a hydrolyzed (OH-terminated) surface with NH2 molecules, yielding a nitrogen-terminated surface. In embodiments that utilize an oxygen plasma for activation, an oxygen concentration peak can be formed at the bond interface between non-conductive bonding surfaces.

In some embodiments, the plasma is formed using a nitrogen-containing gas, e.g., N2, and the terminating species includes nitrogen, or nitrogen and hydrogen. In some embodiments, fluorine may also be present within the plasma. In some embodiments, the surfaces may be activated using a wet cleaning process, e.g., by exposing the surfaces to an aqueous ammonia solution. In some embodiments, the dielectric bonds may be formed using a dielectric material layer deposited on only one of the first and second substrates, but not on both. In those embodiments, the direct dielectric bonds may be formed by contacting the deposited dielectric material layer of one of the first and second substrates directly with a bulk material surface (or such a surface with a native oxide) of the other substrate.

Directly forming direct dielectric bonds between substrates may include bringing the prepared and aligned surfaces into direct contact at a temperature less than 150° C., such as less than 100° C., for example, less than 30° C., or about room temperature, e.g., between 20° C. and 30° C. Without intending to be bound by theory, in the case of directly bonding surfaces terminated with nitrogen and hydrogen (e.g., NH₂ groups), it is believed that the hydrogen terminating species diffuse from the interfacial bonding surfaces, and chemical bonds are formed between the remaining nitrogen species during the direct bonding process. In some embodiments, the direct bond is strengthened using an anneal process, where the substrates are heated to and maintained at a temperature of greater than about 30° C. and less than about 450° C., for example, greater than about 50° C. and less than about 250° C., or about 150° C. for a duration of about 5 minutes or more, such as about 15 minutes. Typically, the bonds will strengthen over time even without the application of heat. Thus, in some embodiments, the method does not include heating the substrates.

In embodiments where the substrates are bonded using hybrid bonds, the method may further include planarizing or recessing the metal features below the field surface before contacting and bonding the dielectric material layers. After the dielectric bonds are formed, the substrates may be heated to a temperature of 150° C. or more and maintained at the elevated temperature for a duration of about 1 hour or more, such as between 8 and 24 hours, to form direct metallurgical bonds between the metal features.

Suitable direct dielectric and hybrid bonding technologies that may be used to perform aspects of the methods described herein include ZiBond® and DBI®, each of which are commercially available from Adeia, San Jose, CA, USA.

The embodiments discussed above are intended to be illustrative and not limiting. One skilled in the art would appreciate that individual aspects of the integrated circuits and components, and methods discussed herein may be omitted, modified, combined, and/or rearranged without departing from the scope of the claimed subject matter.

1. A component comprising:
a substrate comprising a first side and a second side opposite to the first side;
a first dielectric layer formed on the first side and comprising a plurality of electrically conductive pads extending through the first dielectric layer;
a second dielectric layer formed on the second side and comprising a plurality of electrically conductive pads extending through the second dielectric layer; and
a plurality of capacitors, each of the capacitors comprising at least three electrodes and formed in an opening that extends at least partially from the first side towards the second side of the substrate, wherein at least one of the plurality of capacitors is coupled on the first side to a first electrically conductive pad of the first dielectric layer and is coupled on the second side to a second electrically conductive pad of the second dielectric layer.

2. The component of claim 1, further comprising:
a first integrated circuit device attached to the first dielectric layer and electrically coupled to at least one of the electrically conductive pads of the first dielectric layer.

3. The component of claim 1, wherein:
a first of the at least three electrodes of a first capacitor of the plurality of capacitors is coupled to ground and the second and third of the at least three electrodes are coupled to power; and
a first of the at least three electrodes of a second capacitor of the plurality of capacitors is coupled to power and the second and third of the at least three electrodes are coupled to ground.

4. The component of claim 3, wherein:
at least one of the plurality of capacitors comprises a first conductive layer, a second conductive layer, and a plurality of dielectric layers separating the first and second conductive layers; and
the first conductive layer is coupled to a first electrically conductive pad of the first dielectric layer forming the first electrode and the second conductive layer is coupled to a second electrically conductive pad of the first dielectric layer forming the second electrode.

5. The component of claim 4, wherein the first dielectric layer is a redistribution layer further comprising a plurality of conductive layers formed in the first dielectric layer, the plurality of conductive layers electrically coupling at least a group of the plurality of capacitors to each other.

6. The component of claim 5, wherein at least a group of the plurality of conductive layers formed in the first dielectric layer comprises:
a third conductive layer electrically coupling the first conductive layer of each capacitor of the group; and
a fourth conductive layer electrically coupling the second conductive layer of each capacitor of the group.

7. The component of claim 4, wherein the outermost conductive layer of each capacitor comprises either the first conductive layer or the second conductive layer, and wherein the outermost conductive layer of each capacitor is coupled to a first electrically conductive pad of the second dielectric layer forming the third electrode of the capacitor.

8. The component of claim 7, wherein the first conductive layer is capable of carrying power and wherein the second conductive layer is capable of carrying ground.

9. The component of claim 1, further comprising a via formed in the substrate, wherein the via comprises a conductive layer and the conductive layer is coupled to a third electrically conductive pad extending through the first dielectric layer and a second electrically conductive pad extending through the second dielectric layer.

10. The component of claim 8, wherein the conductive layer is capable of carrying a signal.

11. The component of claim 1, wherein the plurality of capacitors are coupled to one of the electrically conductive pads of the second dielectric layer.

12. The component of claim 1, further comprising:
an integrated circuit device attached to the second dielectric layer and electrically coupled to at least one of the electrically conductive pads of the second dielectric layer, wherein the second dielectric layer is a redistribution layer further comprising a plurality of conductive layers formed in the second dielectric layer, the plurality of conductive layers electrically coupling at least a group of the plurality of capacitors to each other and forming the third electrode of each capacitor of the group.

13. The component of claim 2, further comprising:
a hybrid bonding interface formed directly between the first dielectric layer and the first integrated circuit device.

14. The component of claim 1, wherein the substrate is amorphous or crystalline.

15. The component of claim 1, wherein the plurality of capacitors comprise pass-through capacitors.

16. A method of forming a plurality of capacitors, the method comprising:
forming a plurality of openings on a first side of a substrate, the substrate comprising the first side and a second side opposite the first side;
patterning a capacitor in each of the plurality of openings, each capacitor comprising at least three electrodes;
etching a portion of the second side of the substrate to reveal a portion of each of the capacitors;
forming a first dielectric layer on the first side of the substrate, the first dielectric layer comprising a first plurality of electrically conductive pads extending through the first dielectric layer and coupled to the capacitors; and
forming a second dielectric layer on the second side of the substrate, the second dielectric layer comprising a second plurality of electrically conductive pads extending through the second dielectric layer and coupled to the capacitors.

17. (canceled)

18. The method of claim 16, wherein:
a first of the at least three electrodes of a first capacitor of the plurality of capacitors is coupled to ground and the second and third of the at least three electrodes are coupled to power; and
a first of the at least three electrodes of a second capacitor of the plurality of capacitors is coupled to power and the second and third of the at least three electrodes are coupled to ground; and
the method further comprises:
forming a first conductive layer, a second conductive layer, and a plurality of dielectric layers separating the first and second conductive layers in each of the plurality of capacitors;
coupling the first conductive layer to a first electrically conductive pad of the first dielectric layer forming the first electrode; and
coupling the second conductive layer to a second electrically conductive pad of the first dielectric layer forming the second electrode.

19. The method of claim 18, further comprising forming a plurality of conductive layers in the first dielectric layer, the plurality of conductive layers electrically coupling the plurality of capacitors to each other.

20. The method of claim 19, wherein forming the plurality of conductive layers in the first dielectric layer further comprises:
forming a third conductive layer electrically coupling the first conductive layer of each capacitor; and
forming a fourth conductive layer electrically coupling the second conductive layer of each capacitor.

21. The method of claim 18, wherein:
the outermost conductive layer of each capacitor comprises either the first conductive layer or the second conductive layer;
the first conductive layer is capable of carrying power;
the second conductive layer is capable of carrying ground; and
the method further comprises coupling the outermost conductive layer of each capacitor to a first electrically conductive pad of the second dielectric layer forming the third electrode of the capacitor.

22-29. (canceled)
